(19) United States
(12) Patent Application Publication
(10) Pub. No.: US 2014/0175495 A1
(43) Pub. Date: Jun. 26, 2014

(54) DIE BONDING METHOD AND DIE BONDING STRUCTURE OF LIGHT EMITTING DIODE PACKAGE

(71) Applicant: INDUSTRIAL TECHNOLOGY RESEARCH INSTITUTE, Hsinchu (TW)

(72) Inventors: Tung-Han Chuang, Taipei (TW); Jian-Shian Lin, Yilan County (TW); Ying-Tsun Su, Taipei (TW); Meng-Chi Huang, Taoyuan County (TW)

(21) Appl. No.: 13/901,816

(22) Filed: May 24, 2013

(30) Foreign Application Priority Data
Dec. 21, 2012 (TW) 101149187

(51) Int. Cl. H01L 33/48

(52) U.S. Cl. CPC H01L 33/48
USPC 257/99; 438/22

(57) ABSTRACT

A die bonding method and a die bonding structure of a light emitting diode package are provided. The die bonding structure includes a light transmissive adhesive layer formed on a surface of a base plate of a light emitting diode chip, a first metal layer formed on the adhesive layer, a second metal layer formed on a packaging base plate and multiple metallic compound layers. The metallic compound layers are formed by spreading a third metal layer disposed on at least one of the first metal layer and the second metal layer into the first metal layer and the second metal layer after the third metal layer is heated up. The melting points of the first metal layer and the second metal layer are higher than the melting point of the third metal layer.

### CROSS-REFERENCE TO RELATED APPLICATIONS

This non-provisional application claims priority under 35 U.S.C. §119(a) on Patent Application No(s). 101149187 filed in Taiwan, R.O.C. on Dec. 21, 2012, the entire contents of which are hereby incorporated by reference.

### TECHNICAL FIELD

The disclosure relates to a light emitting diode package.

### BACKGROUND

Since a light emitting diode (LED) has the advantages of being compact and having a high luminous efficiency, high life expectancy and a wide color gamut, it is expected that the applications of the light emitting diode will increase. Generally speaking, before a LED chip is commercialized for clients, a light emitting diode bare chip has to undergo packaging procedures of die bonding, wire bonding, encapsulation and merchandise classification.

A light emitting diode component can be prevented from being damaged when die bonding is performed under a low temperature. Also, the die bonding structure will have better heat conductivity for achieving better heat dissipation effects when the LED package is under operation, in order to ensure the luminous efficiency of the LED component.

Conventional die bonding materials are divided into two major types. The first type is high polymeric electrically conductive glue and the second type is metallic solder materials.

In a conventional die bonding method for a light emitting diode, high polymeric electrically conductive glue (e.g. electrically conductive silver paste) is used to adhere a light emitting diode chip on a lead frame, and is heated up at 150° C. for more than one and a half hours for thermosetting the electrically conductive silver paste, in order that the light emitting diode chip is fixed on the lead frame. For example, in Taiwan Patent Publication No. 463394 entitled “Chip-Type LED and Manufacturing Method Thereof”, the patent employs a high polymeric electrically conductive glue (e.g. electrically conductive silver paste) to couple a die with a base plate (lead frame or printed circuit board), and then both are placed into an air furnace for thermal curing.

High polymeric glue has very poor heat conductivity and heat resistance under high operational temperatures so the second silver paste layer may degrade easily over a long period of usage. Consequently, the light emitting diode chip is unable to couple with the lead frame properly. Also, because it is difficult for the silver paste to conduct heat (the thermal conductivity coefficient of the silver paste is only 1 W/M-K), the light emitting diode may be unable to dissipate heat properly. As a result, the life expectancy of the light emitting diode is shortened and its photoelectric conversion efficiency is reduced.

Moreover, the light emitting diode chip can also be fixed on the lead frame using a metallic solder material. Thus, the heat dissipation and heat resistance of the bonding material between the light emitting diode chip and the lead frame can be enhanced. Since the bonding layer formed by eutectic bonding is metallic material, its heat dissipation and heat resistance are better than those of high polymeric electrically conductive glue. In comparing with the die bonding using silver paste, however, the equipment for die bonding is relatively more complicated and expensive, and the production capacity is relatively lower because a temperature controlling system and a pressurization system are required additionally for die bonding equipment using metallic solder material.

### SUMMARY

In an embodiment, a method for die bonding is disclosed. In the method, a light transmissive adhesive layer is formed on a surface of a base plate of a light emitting diode chip. A first metal layer is formed on the adhesive layer. A second metal layer formed on a packaging base plate. A third metal layer is formed on at least one of the first metal layer and the second metal layer. The melting point of the at least one third metal layer is lower than the melting points of the first metal layer and the second metal layer. The first metal layer, the second metal layer and the at least one third metal layer is superimposed with each other so as to bond the light emitting diode chip and the packaging base plate with each other. The bonded light emitting diode chip and the packaging base plate are heated up so as to spread the at least one third metal layer into the first metal layer and the second metal layer to form a metallic compound layer respectively.

The disclosure further provides a die bonding structure comprising a light transmissive adhesive layer, a first metal layer, a second metal layer and a plurality of metallic compound layers. The light transmissive adhesive layer is formed on a surface of a base plate of a light emitting diode chip. The first metal layer is formed on the adhesive layer. The second metal layer is formed on a packaging base plate. The metallic compound layers are formed between the first metal layer and the second metal layer. The metallic compound layers are respectively formed by spreading a third metal layer formed on at least one of the first metal layer and the second metal layer into the first metal layer and the second metal layer when the die bonding structure is heated up. The melting point of the at least one third metal layer is lower than the melting points of the first metal layer and the second metal layer.

### BRIEF DESCRIPTION OF THE DRAWINGS

The disclosure will become more fully understood from the detailed description given herein below for illustration only, and thus does not limit the disclosure, wherein:

FIGS. 1A to 1F are illustrations of a die bonding method according to an embodiment of the disclosure;

FIGS. 2A to 2F are illustrations of the die bonding method according to an embodiment of the disclosure; and

FIGS. 3A to 3G are illustrations of the die bonding method according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

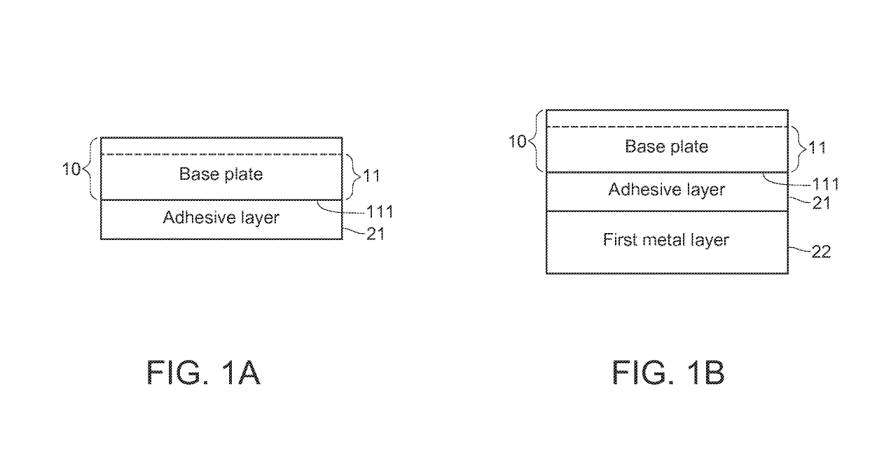

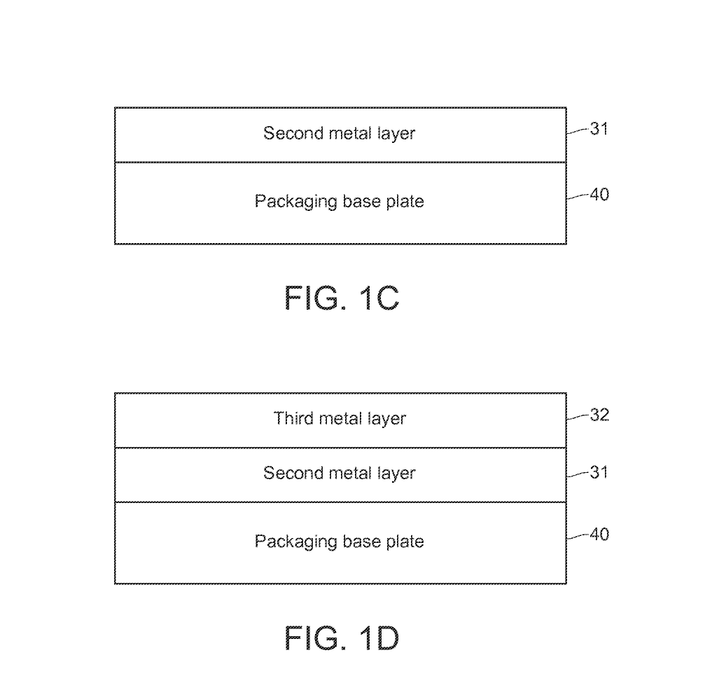

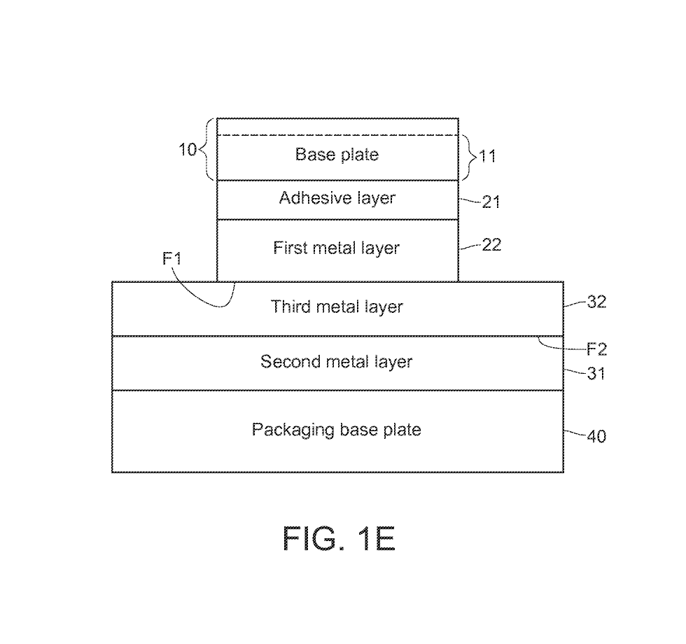

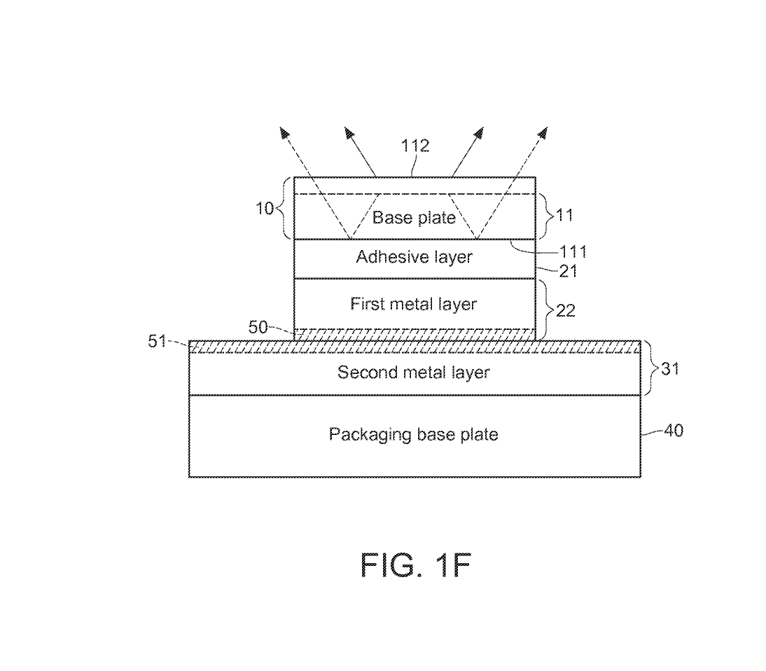

Please refer to FIGS. 1A to 1F for a die bonding method of a light emitting diode package according to an embodiment of the disclosure. FIG. 1F is a structural illustration of the light emitting diode package of the disclosure. The light emitting diode package of the disclosure comprises a light emitting diode chip 10, a die bonding structure and a packaging base plate 40.

Firstly, an adhesive layer 21 is formed on a surface 111 of a base plate 11 of the light emitting diode chip 10, and a first metal layer 22 is formed on the adhesive layer 21, as shown in FIGS. 1A and 1B. And, a second metal layer 31 is formed on the packaging base plate 40, and a third metal layer 32 is formed on the second metal layer 31, as shown in FIGS. 1C and 1D.

Then, the first metal layer 22 and the third metal layer 32 are superimposed with each other to cause the adhesive layer 21, the first metal layer 22, the third metal layer 32 and the second metal layer 31 to superimpose with each other sequentially from the light emitting diode chip 10 toward the packaging base plate 40. Thereby, the light emitting diode chip 10 and the packaging base plate 40 are bonded with each other, as shown in FIG. 1E.

In an embodiment, the method for bonding the light emitting diode chip 10 and the packaging base plate 40 may be achieved by employing a die bonding machine to cause the first metal layer 22 and the third metal layer 32 to contact with each other. Under a certain bonding temperature (e.g. 110° C.), a certain bonding pressure (e.g. 1000 Newtons) is then exerted on the light emitting diode chip 10 plated with the first metal layer 22 and the packaging base plate 40 plated with the second metal layer 31 and the third metal layer 32 for a certain time period (e.g. 5 seconds) in order to bond the light emitting diode chip 10 and the packaging base plate 40 together.

Lastly, the bonded light emitting diode chip 10 and the packaging base plate 40 are heated up by placing both into a high temperature furnace for performing an isothermal solidification process.

When the semi-finished die bonding structure in FIG. 1E is heated up, the third metal layer 32 is fused. The liquefied third metal layer 32 then spreads toward the first metal layer 22 and the second metal layer 31 respectively to cause solid phase reaction and liquid phase reaction to occur respectively at a bonding interface F1 between the first metal layer 22 and the third metal layer 32 and a bonding interface F2 between the third metal layer 32 and the second metal layer 31 so as to form a metallic compound layer 50 and a metallic compound layer 51 respectively. At the end of the spreading of the third metal layer 32, the third metal layer 32 will be consumed completely as shown in FIG. 1F. An area of the metallic compound layer 50 may be equal to that of the first metal layer 22. An area of the metallic compound layer 51 may be equal to that of the second metal layer 31.

The isothermal solidification process is referred to the bonding process between the light emitting diode chip 10 and the packaging base plate 40 is performed under a constant temperature, and the fused third metal layer 32 is changed into solid intermetallic compounds, namely the metallic compound layer 50 and the metallic compound layer 51.

In an embodiment, the thicknesses of the first metal layer 22 and the second metal layer 31 are depended on the thickness of the third metal layer 32. That is, the first metal layer 22 and the second metal layer 31 are remained with a certain thickness respectively after the third metal layer 32 is consumed completely during the heat up process. Furthermore, the remained thickness of the first metal layer 22 does not have to be the same as the remained thickness of the second metal layer 31.

In another embodiment, after the third metal layer 32 and the second metal layer 31 are consumed completely during the heat up process, the first metal layer 22 is remained with a certain thickness.

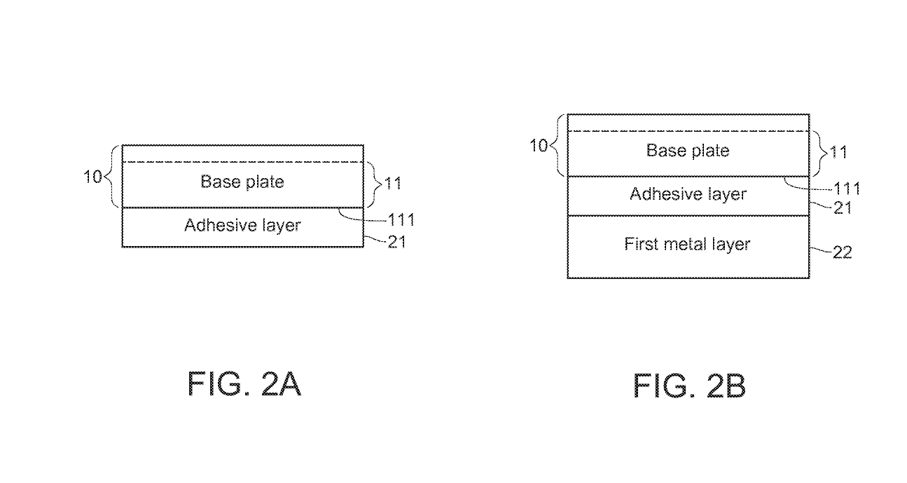

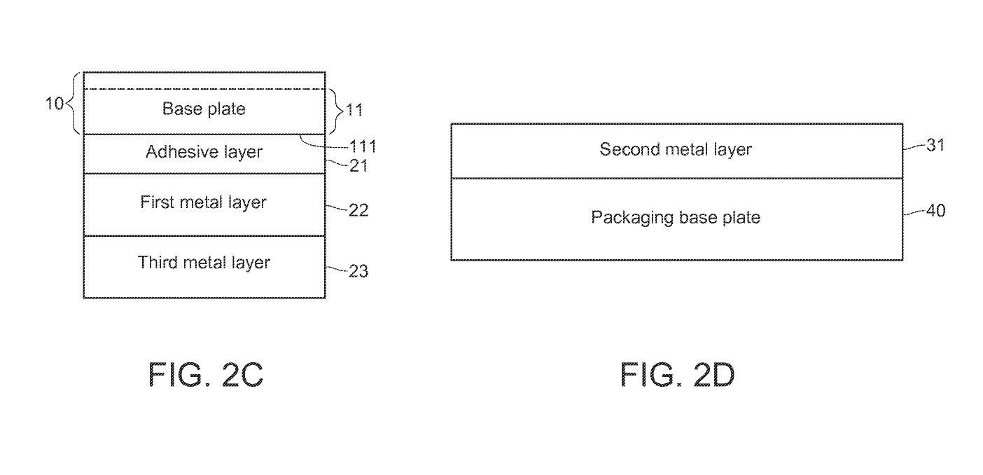

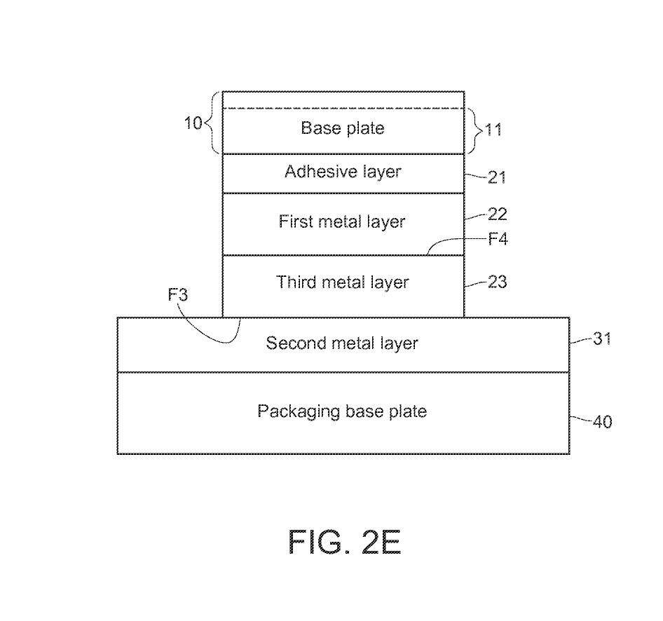

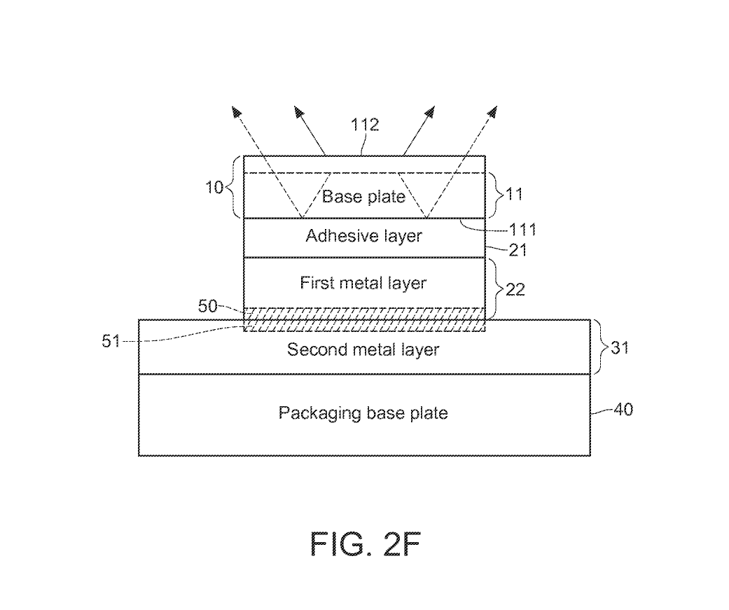

As for the die bonding method of the light emitting diode package according to an embodiment of the disclosure, please refer to FIGS. 2A to 2F. FIG. 2F is a structural illustration of the light emitting diode package of the disclosure. The light emitting diode package of the disclosure comprises the light emitting diode chip 10, the die bonding structure and the packaging base plate 40.

Firstly, the adhesive layer 21 is formed on the surface 111 of the base plate 11 of the light emitting diode chip 10, the first metal layer 22 is formed on the adhesive layer 21, and a third metal layer 23 is formed on the first metal layer 22, as shown in FIGS. 2A to 2C. And, the second metal layer 31 is formed on the packaging base plate 40, as shown in FIG. 2D.

Then, the third metal layer 23 and the second metal layer 31 are superimposed with each other to cause the adhesive layer 21, the first metal layer 22, the third metal layer 23 and the second metal layer 31 to superimpose with each other sequentially from the light emitting diode chip 10 toward the packaging base plate 40. Thereby, the light emitting diode chip 10 and the packaging base plate 40 are bonded with each other, as shown in FIG. 2E.

Lastly, the bonded light emitting diode chip 10 and the packaging base plate 40 are heated up by placing both into a high temperature furnace for performing an isothermal solidification process.

When the semi-finished die bonding structure in FIG. 2E is heated up, the third metal layer 23 is fused. The liquefied third metal layer 23 then spreads toward the first metal layer 22 and the second metal layer 31 respectively to cause solid phase reaction and liquid phase reaction to occur respectively at a bonding interface F4 between the first metal layer 22 and the third metal layer 23 and a bonding interface F3 between the third metal layer 23 and the second metal layer 31 so as to form the metallic compound layer 50 and the metallic compound layer 51 respectively. At the end of the spreading of the third metal layer 23, the third metal layer 23 is consumed completely as shown in FIG. 2F. An area of the metallic compound layer 50 may be equal to that of the first metal layer 22. An area of the metallic compound layer 51 may be equal to that of the second metal layer 31.

In an embodiment, the thicknesses of the first metal layer 22 and the second metal layer 31 are depended on the thickness of the third metal layer 23. That is, the first metal layer 22 and the second metal layer 31 are remained with a certain thickness respectively after the third metal layer 23 is consumed completely during the heat up process. Moreover, the remained thickness of the first metal layer 22 does not have to be the same as the remained thickness of the second metal layer 31.

In another embodiment, after the third metal layer 23 and the second metal layer 31 are consumed completely during the heat up process, the first metal layer 22 is remained with a certain thickness.

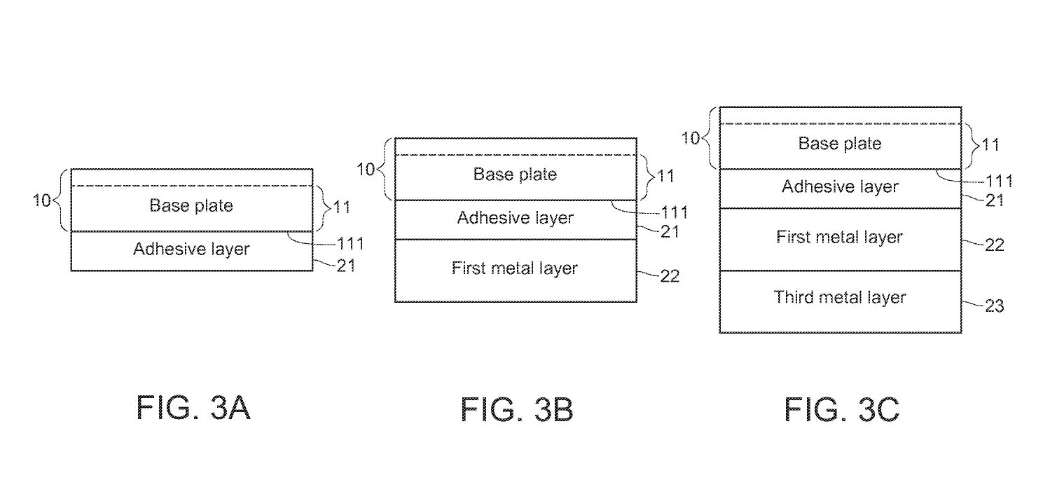

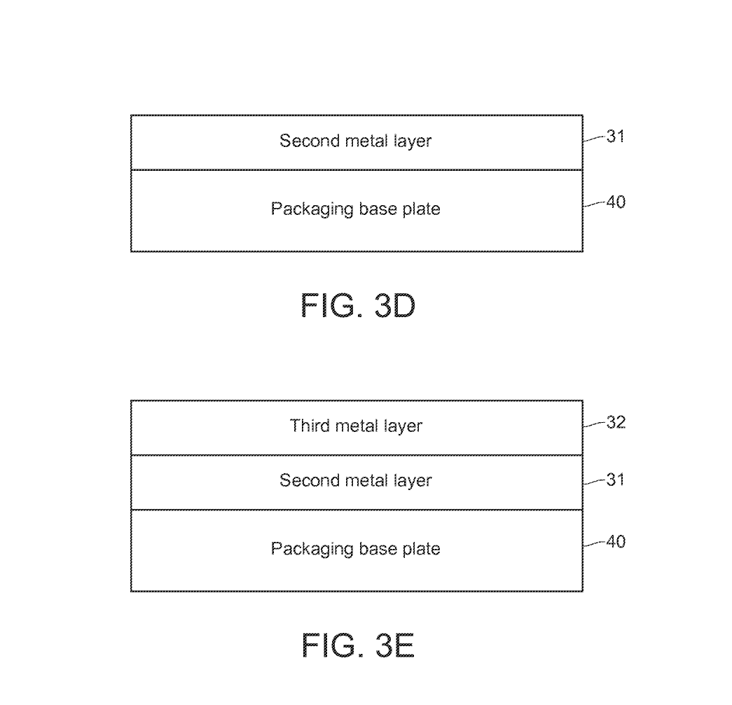

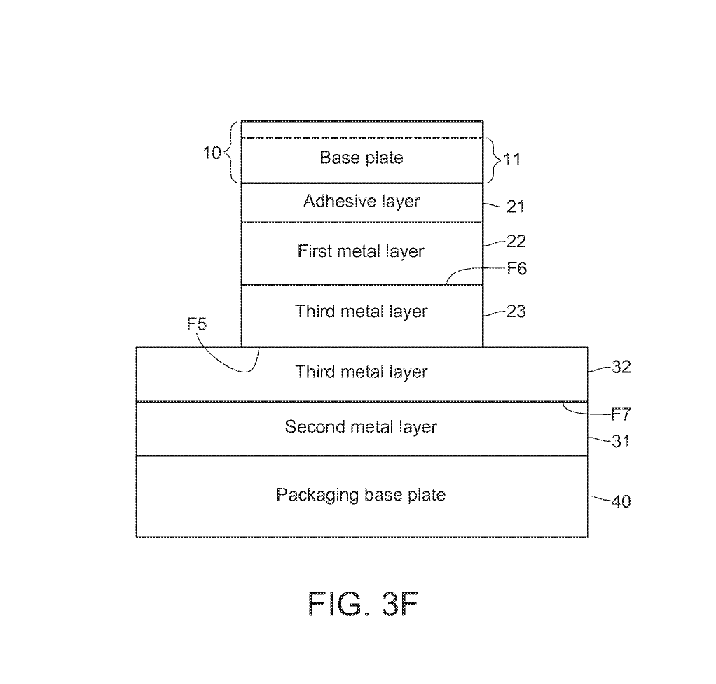

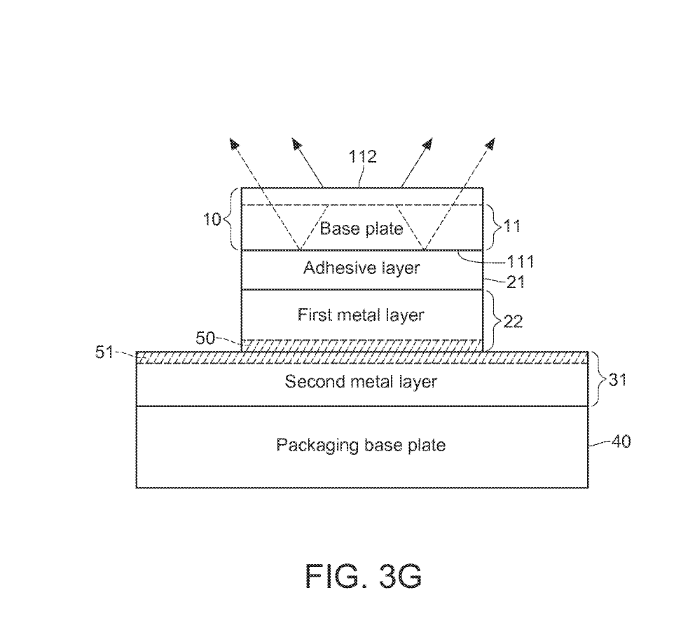

Please refer to FIGS. 3A to 3G for the die bonding method of the light emitting diode package according to an embodiment of the disclosure. FIG. 3G is a structural illustration of the light emitting diode package of the disclosure. The light emitting diode package of the disclosure comprises the light emitting diode chip 10, the die bonding structure and the packaging base plate 40.

Firstly, the adhesive layer 21 is formed on the surface 111 of the base plate 11 of the light emitting diode chip 10, the first metal layer 22 is formed on the adhesive layer 21, and the third metal layer 23 is formed on the first metal layer 22, as shown in FIGS. 3A to 3C. Furthermore, the second metal layer 31 is formed on the packaging base plate 40, and the other third metal layer 32 is formed on the second metal layer 31, as shown in FIGS. 3D and 3E.

Then, the third metal layer 23 and the third metal layer 32 are superimposed with each other to cause the adhesive layer 21, the first metal layer 22, the third metal layer 23, the third metal layer 32 and the second metal layer 31 to superimpose with each other sequentially from the light emitting diode chip 10 toward the packaging base plate 40. Thereby, the light emitting diode chip 10 and the packaging base plate 40 are bonded with each other, as shown in FIG. 3F.

Lastly, the bonded light emitting diode chip 10 and the packaging base plate 40 are heated up by placing both into a high temperature furnace for performing an isothermal solidification process.

When the semi-finished die bonding structure in FIG. 3F is heated up, the third metal layer 23 and the third metal layer 32 is fused. The liquefied third metal layer 23 and the third metal layer 32 then bond with each other at a bonding interface F5, and spread toward the first metal layer 22 and the second metal layer 31 respectively to cause solid phase reaction and liquid phase reaction to occur respectively at a bonding interface F6 between the first metal layer 22 and the third metal layer 23 and a bonding interface F7 between the third metal layer 32 and the second metal layer 31 to form the metallic compound layer 50 and the metallic compound layer 51 respectively. At the end of the spreading of the third metal layer 23 and the third metal layer 32, the third metal layer 23 and the third metal layer 32 are consumed completely as shown in FIG. 3G. An area of the metallic compound layer 50 may be equal to that of the first metal layer 22. An area of the metallic compound layer 51 may be equal to that of the second metal layer 31.

In an embodiment, the thicknesses of the first metal layer 22 and the second metal layer 31 are depended on the thicknesses of the third metal layer 23 and the third metal layer 32. That is, the first metal layer 22 and the second metal layer 31 are remained with a certain thickness respectively after the third metal layer 23 and the third metal layer 32 are consumed completely during the heat up process. Moreover, the remained thickness of the first metal layer 22 does not have to be the same as the remained thickness of the second metal layer 31.

In another embodiment, when the third metal layer 23, the third metal layer 32 and the second metal layer 31 are consumed completely during the heat up process, the first metal layer 22 is remained with a certain thickness.

By using the die bonding structure of the disclosure, the light radiated by the light emitting diode chip 10 is not only emitted through its emitting surface 112 (as indicated by the solid lines), the light of the light emitting diode chip 10 penetrating through the base plate 11 downwardly (as indicated by the dotted lines) may also emit from the emitting surface 112 after reflected by the first metal layer 22. The reflectivity of the first metal layer 22 may reach up to 91% to 96%. Thereby, the light exitance of the light emitting diode package is enhanced, and therefore the luminous efficiency is enhanced.

The adhesive layer 21 of the disclosure may be formed by evaporation deposition or sputtering deposition. The adhesive layer 21 is light transmissive. The adhesive layer 21 may be made of metallic film or metal-oxide film such as aluminum or aluminum oxide (Al₂O₃), and the thickness of the film may be between 10 nanometers (nm) and 1 micron (um). The light transmittance of the adhesive layer 21 is referred to the adhesive layer 21 at least allows the light radiated by the light emitting diode chip 10 to transmit through.

The first metal layer 22 of the disclosure may be formed by evaporation deposition, sputtering deposition, electroplating or deposition. The first metal layer 22 is reflective. The first metal layer 22 can be made of silver, aluminum or an alloy composed of silver or aluminum. The thickness of the first metal layer 22 may be between 0.1 micron and 10 microns.

The second metal layer 31 of the disclosure can be formed on the packaging base plate 40 by evaporation deposition, sputtering deposition, electroplating or deposition. The second metal layer 31 may be made of silver (Ag), copper (Cu), nickel (Ni) or an alloy composed of silver, copper or nickel. The thickness of the second metal layer 31 may be between 0.1 micron and 10 microns.

The melting points of the third metal layer 23 and the third metal layer 32 of the disclosure are lower than the melting points of the first metal layer 22 and the second metal layer 31. The third metal layer 23 and the third metal layer 32 may be made of tin (Sn), indium (In) or indium-tin (InSn). The thicknesses of the third metal layer 23 and the third metal layer 32 may be between 1 micron and 20 microns. In an embodiment, when the third metal layer 32 is a composite metal layer, the disposing sequence of each of the materials may be designed based on requirements.

The material of the metallic compound layer 50 of the disclosure is depended on the materials of the first metal layer 22 and the third metal layer 32, or is depended on the materials of the first metal layer 22 and the third metal layer 23. Therefore, the metallic compound layer 50 may be made of tin-silver (Ag₃Sn) or indium-silver (Ag₂In). The material of the metallic compound layer 51 is depended on the materials of the third metal layer 32 and the second metal layer 31, or is depended on the materials of the third metal layer 23 and the second metal layer 31. Therefore, the metallic compound layer 51 is made of benign tin-copper (Cu₆Sn₅), malignant tin-copper (Cu₃Sn), tin-nickel (Ni₃Sn₄), indium-copper (Cu₇In₃) or indium-nickel (Ni₃In).

The melting point of tin-silver (Ag₃Sn) is 480° C. The melting point of indium-silver (Ag₂In) is 305° C. The melting point of benign tin-copper (Cu₆Sn₅) is 415° C. The melting point of malignant tin-copper (Cu₃Sn) is 670° C. The melting point of tin-nickel (Ni₃Sn₄) is 795° C. The melting point of indium-copper (Cu₇In₃) is 610° C. The melting point of indium-nickel (Ni₃In) is 776° C.

The light emitting diode chip 10 of the disclosure is not limited to any particular materials, structures and manufacturing processes, and a wavelength of the light radiated by the light emitting diode chip 10 may be designed or selected according to the users' requirements. Therefore, the light emitting diode chip 10 can have a p-i-n structure, and may be made of gallium nitride (GaN), gallium-indium nitride (GaInN), aluminum-indium-gallium phosphide (AlInGaP), aluminum-indium-gallium nitride (AlInGaN), aluminum nitride (AlN), indium nitride (InN), gallium-indium-arsenic nitride (GaInAsN), gallium-indium phosphorus nitride (GaInPN) or a combination of the above.

The base plate 11 of the disclosure is a transparent base plate with the property of light transmittance. The base plate 11 may be a sapphire base plate, a silicon (Si) base plate or a carborundum (SiC) base plate. Furthermore, the base plate 11 may also be a mono-crystalline base plate. The packaging base plate 40 may be a lead frame, a printed circuit board, a substrate material with plastic reflection cup or a ceramic base plate. The packaging base plate 40 may be made of silver (Ag), copper (Cu), Kovar, ferric nickel (FeNi), aluminum (Al), aluminum nitride (AIN), silicon (Si) or low-temperature co-fired ceramics (LTCC).

In an embodiment, the adhesive layer 21 is made of aluminum oxide, the first metal layer 22 is made of silver, and the second metal layer 31 is made of tin. The thickness of the adhesive layer 21 is 50 nm, the thickness of the first metal layer 22 is between 6 and 10 um, and the thickness of the second metal layer 31 is 4 um. In this embodiment, the reflectivity of the adhesive layer 21 is able to reach up to 91%.

In an embodiment, the adhesive layer 21 is made of aluminum, the first metal layer 22 is made of silver, and the second metal layer 31 is made of tin. The thickness of the adhesive layer 21 is 1 um, the thickness of the first metal layer 22 is between 6 and 10 um, and the thickness of the second metal layer 31 is 4 um. In this embodiment, the reflectivity of the adhesive layer 21 is capable of reaching up to 96%.

According to the die bonding method, the die bonding structure and the light emitting diode package disclosed by the disclosure, the light transmissive adhesive layer is formed on the surface of the base plate of the light emitting diode chip, and the reflective first metal layer is then formed on the adhesive layer, in order that the light penetrating through the base plate of the light emitting diode chip is able to be reflected by the first metal layer. Thereby, the luminous efficiency of the light emitting diode package is enhanced.

Furthermore, by employing the superimposed structure of the at least one third metal layer, the first metal layer and the second metal layer (the melting point of the third metal layer is lower than the melting points of the first metal layer and the second metal layer), when the die bonding structure is heated up, solid phase reaction and liquid phase reaction respectively occur at the interfaces between the third metal layer and the first metal layer as well as the second metal layer to form the metallic compound layers. Thereby, the bonding interface between the first superimposed structure and the second superimposed structure can endure relatively higher temperatures, and the objectives of bonding at low temperatures and application at high temperatures are achieved.

What is claimed is:

1. A die bonding method, comprising steps of:
forming a light transmissive adhesive layer on a surface of a base plate of a light emitting diode chip;
forming a first metal layer on the adhesive layer;
forming a second metal layer on a packaging base plate;
forming a third metal layer on at least one of the first metal layer and the second metal layer, wherein the melting point of the at least one third metal layer is lower than the melting points of the first metal layer and the second metal layer;
superimposing the first metal layer, the second metal layer and the at least one third metal layer with each other so as to bond the light emitting diode chip and the packaging base plate with each other; and
heating up the bonded light emitting diode chip and the packaging base plate so as to spread the at least one third metal layer into the first metal layer and the second metal layer to form a metallic compound layer respectively.

2. The die bonding method as claimed in claim 1, wherein the material of the first metal layer is silver, aluminum or an alloy composed of silver or aluminum.

3. The die bonding method as claimed in claim 1, wherein the material of the second metal layer is silver, copper, nickel or an alloy composed of silver, copper or nickel.

4. The die bonding method as claimed in claim 1, wherein the material of the at least one third metal layer is bismuth, indium, tin, or an alloy composed of bismuth, indium or tin.

5. The die bonding method as claimed in claim 1, wherein the base plate of the light emitting diode chip is a sapphire base plate, a silicon base plate or a carborundum base plate.

6. The die bonding method as claimed in claim 1, wherein the adhesive layer is a metallic film or a metal-oxide film.

7. The die bonding method as claimed in claim 1, wherein the material of the adhesive layer is aluminum or aluminum oxide.

8. The die bonding method as claimed in claim 1, wherein the thickness of the adhesive layer is between 10 nanometers and 1 micron.

9. The die bonding method as claimed in claim 1, wherein the thickness of the first metal layer is between 0.1 micron and 10 microns.

10. The die bonding method as claimed in claim 1, wherein the thickness of the second metal layer is between 0.1 micron and 10 microns.

11. The die bonding method as claimed in claim 1, wherein the thickness of the third metal layer is between 1 micron and 20 microns.

12. The die bonding method as claimed in claim 1, wherein the material of the packaging base plate is silver, copper, ferric nickel, aluminum or aluminum nitride, or the packaging base plate is a copper or silver lead frame.

13. A die bonding structure, comprising:
a light transmissive adhesive layer formed on a surface of a base plate of a light emitting diode chip;
a first metal layer formed on the adhesive layer;
a second metal layer formed on a packaging base plate; and
a plurality of metallic compound layers formed between the first metal layer and the second metal layer;
wherein the metallic compound layers are respectively formed by spreading a third metal layer formed on at least one of the first metal layer and the second metal layer into the first metal layer and the second metal layer when the die bonding structure is heated up, and the melting point of the at least one third metal layer is lower than the melting points of the first metal layer and the second metal layer.

14. The die bonding structure as claimed in claim 13, wherein the material of the first metal layer is silver, aluminum or an alloy composed of silver or aluminum.

15. The die bonding structure as claimed in claim 13, wherein the material of the second metal layer is silver, copper, nickel or an alloy composed of silver, copper or nickel.

16. The die bonding structure as claimed in claim 13, wherein the material of the at least one third metal layer is bismuth, indium, tin, or an alloy composed of bismuth, indium or tin.

17. The die bonding structure as claimed in claim 13, wherein the base plate of the light emitting diode chip is a sapphire base plate, a silicon base plate or a carborundum base plate.

18. The die bonding structure as claimed in claim 13, wherein the adhesive layer is a metallic film or a metal-oxide film.

19. The die bonding structure as claimed in claim 13, wherein the material of the adhesive layer is aluminum or aluminum oxide.

20. The die bonding structure as claimed in claim 13, wherein the thickness of the adhesive layer is between 10 nanometers and 1 micron.

21. The die bonding structure as claimed in claim 13, wherein the thickness of the first metal layer is between 0.1 micron and 10 microns.

22. The die bonding structure as claimed in claim 13, wherein the thickness of the second metal layer is between 0.1 micron and 10 microns.

23. The die bonding structure as claimed in claim 13, wherein the thickness of the third metal layer is between 1 micron and 20 microns.

24. The die bonding structure as claimed in claim 13, wherein the material of the packaging base plate is silver, copper, ferric nickel, aluminum or aluminum nitride, or the packaging base plate is a copper or silver lead frame.

25. A light emitting diode package, comprising the light emitting diode chip, the packaging base plate and the die bonding structure as claimed in claim 13, the light emitting diode chip bonding with the packaging base plate through the die bonding structure.
